(19) United States
(12) Patent Application Publication
(10) Pub. No.: US 2013/0213814 A1
(43) Pub. Date: Aug. 22, 2013

(54) FILM INSPECTION METHOD

(71) Applicant: First Solar, Inc., (US)

(72) Inventors: Jianjun Wang, Perrysburg, OH (US); Markus Gloeckler, Perrysburg, OH (US); Long Cheng, Perrysburg, OH (US); Oleh Petro Karpenko, Richmond, CA (US)

(73) Assignee: FIRST SOLAR, INC., PERRYSBURG, OH (US)

(21) Appl. No.: 13/766,069

(22) Filed: Feb. 13, 2013

Related U.S. Application Data
(60) Provisional application No. 61/597,913, filed on Feb. 13, 2012.

(51) Int. Cl. G01N 27/42; H01L 31/18

(52) U.S. Cl. CPC G01N 27/42; H01L 31/186
USPC 205/81; 205/123; 204/434

(57) ABSTRACT

A method for forming a defect marker on a thin film of a photovoltaic device by plating to detect pinholes and/or electrical shunts during device fabrication is disclosed. Also disclosed is a system for implementing such a method.

### CLAIM OF PRIORITY

This application claims priority under 35 U.S.C. §119(e) to U.S. Provisional Patent Application Ser. No. 61/597,913 filed on Feb. 13, 2012, which is hereby incorporated by reference in its entirety.

### TECHNICAL FIELD

This invention relates to a defect detection system and related method.

### BACKGROUND

A photovoltaic (PV) device is a device that converts photo-radiation into electrical current. A typical PV device includes two conductive electrodes sandwiching a series of semiconductor layers, which provide a junction at which the photo-conversion occurs. During operation, photons pass through the PV device layers and are absorbed at or near the junction. This produces photo-generated electron-hole pairs, the movement of which, promoted by a built-in electric field, produces electric current that can be output from the device.

Note that a PV device can be a PV cell, a PV module, etc. A PV module is made of a plurality of PV cells. Note further that PV module and PV device will be used interchangeably throughout the rest of the disclosure.

In manufacturing a PV device, a series of different layer formation/deposition processes may be used. Many deposition processes, such as sputtering or evaporation, can result in layer formation defects. For example, most materials are not continuous arrangements of atoms, but rather, are composed of thousands or millions of microscopic crystals, known as “grains.” The expansion of these individual crystals in a material is called grain growth. Formation of a layer of material is often referred to as grain growth. Uneven grain growth can lead to minute vacancies or discontinuities in the layer. These minute vacancies or discontinuities are often referred to as pinholes, which are formation defects.

When pinholes are in a semiconductor or insulating layer adjacent to a conducting layer, part of the conducting layer may be exposed to materials formed on the opposite side of the semiconductor or insulating layer. In such cases, the pinholes may lead to electrical shorts in the PV device.

Another possible PV device layer formation defect is an electrical shunt. Electrical shunts cause unwanted short currents between front and back contacts of a PV device. Electrical shunts are often formed as a result of impurities in a deposition process. Due to these impurities, unwanted introduction of unintended materials may become part of the formed layer. In cases where there is a high concentration of an unintended material that is electrically conductive, an electrical shunt may develop. Electrical shunts may also be formed when the ratio of the elements in a compound semiconductor is different than the targeted composition. Areas with electrical shunts provide less resistance and carry increased current at operating voltages compared to the surrounding unaffected areas. This, therefore, can lead to electrical shorts in the PV device.

Due to their size and/or visual similarity to the surrounding layer material, pinholes and electrical shunts are difficult to detect during a quality control phase of the manufacturing process. As a result, layers with these formation defects can be incorporated into finished PV devices. PV devices with layers containing pinholes and/or electrical shunts may not perform optimally or may fail prematurely.

A method is therefore needed for more easily detecting these formation defects in a layer of a PV device such that the layer may be excluded from the device, the layer can be repaired, or the manufacturing process can be adjusted to minimize the occurrence of the defect.

### DESCRIPTION OF DRAWINGS

FIG. 1 is a cross-sectional view of an exemplary PV module.

FIG. 2A is a cross-sectional view of a portion of an exemplary PV module.

FIG. 2B is a top view of the portion of the exemplary PV module of FIG. 2A.

FIG. 3 is a diagram illustrating an electroplating system.

FIG. 4A is a cross-sectional view of a portion of an exemplary PV module.

FIG. 4B is a top view of the portion of the exemplary PV module of FIG. 4A.

FIG. 5A is a cross-sectional view of a portion of an exemplary PV module.

FIG. 5B is a top view of the portion of the exemplary PV module of FIG. 5A.

FIG. 6A is a cross-sectional view of a portion of an exemplary PV module.

FIG. 6B is a top view of the portion of the exemplary PV module of FIG. 6A.

FIG. 7A is a top view showing a pinhole defect of a semiconductor layer before plating.

FIG. 7B is a top view showing an enlarged defect marker after plating over the pinhole defect of FIG. 7A.

FIG. 8 is a diagram illustrating a pinhole and shunting path detection mechanism.

FIG. 9 shows inspection of defect markers.

FIG. 10 is a diagram illustrating a defect detection system in a product manufacturing process.

### DETAILED DESCRIPTION

The disclosed invention includes a system and method for improving defect detection in thin films and coatings of a multilayer structure, particularly, but not limited to, structures produced in PV module manufacturing. Such a multilayer structure includes a semiconductor or insulator thin film or coating adjacent to a conductive layer. The disclosed system and method include forming markers at pinholes or electrical shunting spots in the semiconductor or insulator thin film/coating of the multilayer structure by an electroplating process, which deposits metal material on a surface of the thin film/coating at conductive regions of its surface. Such conductive regions correlate to the defects to be marked. The markers formed using the disclosed system and method can be made significantly larger than the defects themselves and, thus, are more readily discoverable during visual inspections by the naked eye or by an automated inspection system. The disclosed method and system utilize plating techniques and apparatus to better identify a defect in the semiconductor or insulator thin film/coating as small as 10 nm by forming a more readily detected marker several hundred microns (μm) in size.

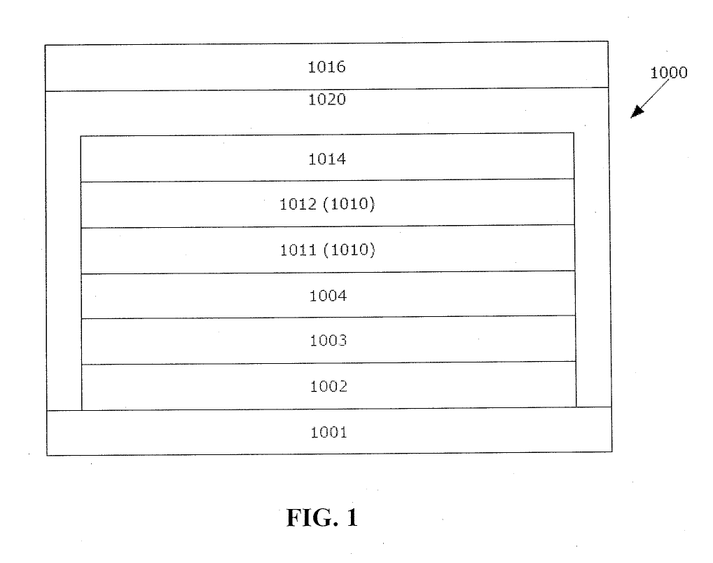

FIG. 1 shows an exemplary PV module 1000. The PV module 1000 has an optically transparent substrate 1001. Suitable transparent materials for the substrate 1001 include glass, such as soda-lime glass or float glass, etc., and polymer (sheet or plates). A first of two conductive electrodes is provided over the transparent substrate 1001. The first conductive electrode can include a transparent conductive oxide (TCO) layer 1003 (e.g., fluorine doped tin oxide or indium tin oxide). The TCO layer 1003 can also be associated with a barrier layer 1002 (e.g., SiO₂ or SnO) between it and the transparent substrate 1001 and a conductive buffer layer 1004 (e.g., a metal chalcogenide material) over the TCO layer 1003, which together provide a TCO stack that functions as the first conductive electrode.

Over the TCO stack (e.g., over the buffer layer 1004 if provided) a semiconductor layer 1010 can be provided. The semiconductor layer 1010 can be a bi-layer that includes a semiconductor window layer 1011 (e.g., cadmium sulfide) and a semiconductor absorber layer 1012 (e.g., cadmium telluride).

Over the semiconductor layer 1010, the second of the two conductive electrodes is provided as a back contact layer 1014 (e.g., a metal or alloy). A back cover 1016 can be provided over the back contact layer 1014 to provide support and protection to the PV module 1000. An interlayer 1020 (e.g., a polymer) can be provided between the back contact layer 1014 and the back cover 1016 and over the sides of the other layers 1002-1012 of the PV module 1000 to seal and protect the inner layers of the PV module 1000 from environmental hazards.

As noted above, both pinholes and electrical shunts may lead to electrical short currents within a PV device and these short currents lead to power loss. This is especially so, if the pinholes and/or shunts are in a semiconductor layer or an insulating layer sandwiched between two conducting layers and a potential difference exists across the semiconductor layer or the insulating layer. For example, if the window layer 1011, which is between the conductive TCO layer 1003 or TCO stack (if a stack is used) and absorber layer 1012, has pinholes therein, a short current may ensue whereby electrical current moves freely between the TCO layer 1003 and the absorber layer 1012. In such cases, the pinholes may be filled in with the material used to form the absorber layer 1012, when the absorber layer 1012 is formed over the window layer 1011. This then may produce an electrical pathway between the TCO layer 1003 or stack and the absorber layer 1012 allowing the current to move freely between the absorber layer 1012 and the TCO layer 1003 or stack.

Likewise, if the absorber layer 1012, which is between the window layer 1011 and the back contact layer 1014, has pinholes therein, the conductive material in the back contact layer 1014 may fill in the pinholes when the back contact layer 1014 is deposited over the absorber layer 1012. An electrical pathway may ensue between the back contact layer 1014 and the window layer 1011 allowing electrical current to freely move between the back contact layer 1014 and the window layer 1011. If the PV module 1000 is fabricated beginning with the back contact layer 1014 followed by the absorber layer 1012, it is also possible for pinholes in the absorber layer 1012 to be filled with material from the subsequently deposited window layer 1013, which would cause similar electrical shorting problems.

In cases of electrical shunts, a high density or concentration of an unintended conductive material in a semiconductor layer or insulating layer sandwiched by two conductive layers may provide an electrical pathway through the semiconductor or insulating layer allowing current to move freely between the two conductive layers.

Thus, a method of identifying these layer formation defects is needed. The present invention will be explained using an electroplating process to detect layer formation defects such as pinholes and electrical shunts.

In an electroplating process a system is used having an anode, a cathode and a solution containing metal ions to coat the cathode with the metal ions. The anode and the cathode are connected to a power supply. Upon applying an electrical current from the power supply, the metal ions in the solution flow toward the cathode where they begin to coat the cathode with a layer of the metal. The process used in electroplating is called electrodeposition. In one technique, the anode is made of the metal to be plated on the cathode. In another technique, the solution contains the metal to be plated.

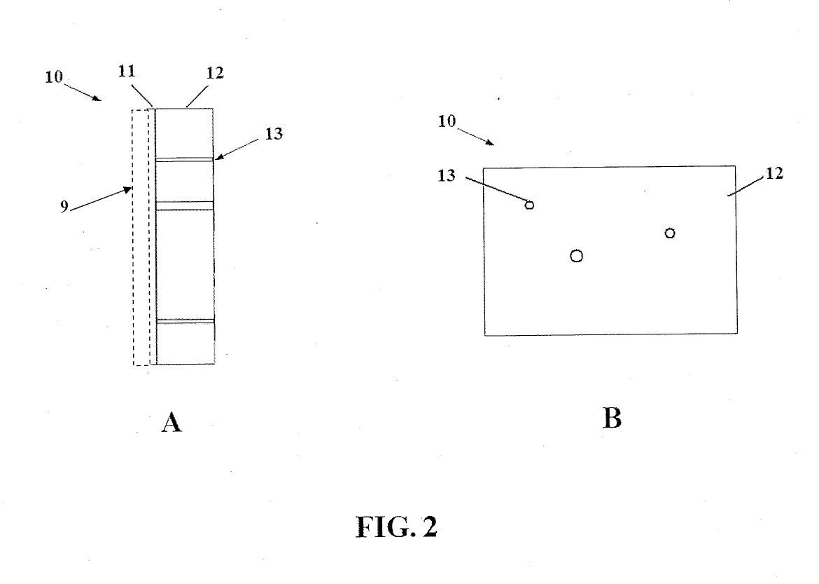

Referring back to the figures, which use like reference numbers to denote like features, FIG. 2A shows a partially manufactured PV module 10 and FIG. 2B illustrates a top view of the partially manufactured PV module 10. The partially manufactured PV module 10 includes a conductive layer 11 (which can be formed over a substrate 9, if desired) and a semiconductor or insulator thin film coating 12. The conductive layer can be any conductive material layer of a PV module, e.g., a cadmium stannate-based, fluorine-doped tin oxide-based, cadmium stearate-based, indium tin oxide-based, cadmium tin-based, aluminum zinc oxide-based, or other conductive material-based TCO layer (or stack) or a molybdenum-based, aluminum-based, copper-based, silver-based, gold-based, or other metal-based back contact layer, so long as it can be connected to a power source and/or used as an electrode. The semiconductor or insulator thin film coating 12 can be, for example, a CdS-based window layer, or a CdTe-based, a-Si-based, CIS-based, or CIGS-based absorber layer. However, other semiconductor or insulator-based layers and other conductive layers of a PV module can also be used. In this particular embodiment, the thin film coating 12 includes a plurality of pinholes 13 as surface defects. The optional substrate 9 can be conductive or insulating and may be, e.g., stainless steel foil or glass.

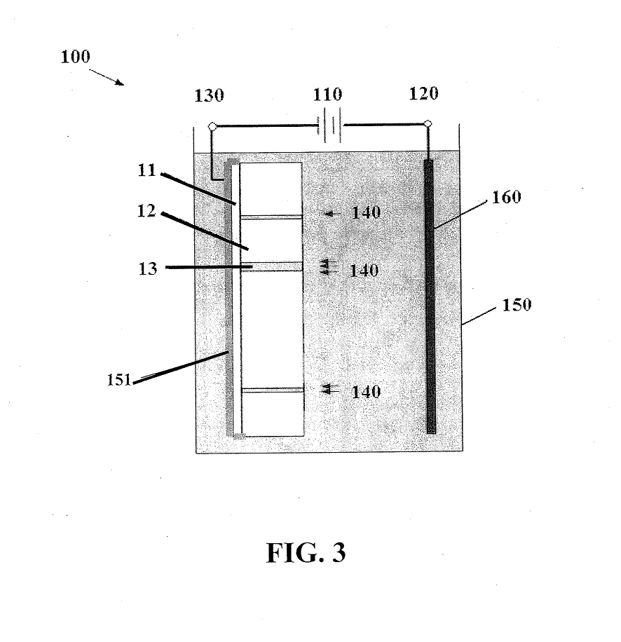

FIG. 3 illustrates an embodiment of an electroplating system 100 used for detecting the pinholes 13 in the semiconductor or insulator thin film coating 12 in FIGS. 2A and 2B. The electroplating system 100 includes a container 150 containing a plating solution 140. The plating solution 140 includes a plating material precursor, e.g., metal ions in solution. As alternatives, the metal ions in solution may be supplied by the solution itself or may originate from an anode 160 of the system 100. As shown in the FIG. 3, the electroplating system 100 is configured to receive a multilayer structure, such as the partially manufactured PV module 10 shown in FIG. 2A.

The electroplating system 100 includes a power source 110 having a positive terminal 120 and a negative terminal 130. The anode 160 is electrically connected to the positive terminal 120 of the power source 110. The conductive layer 11 of the PV module 10 can be electrically connected to the negative terminal 130 of the power source 110, thereby functioning as a cathode. By applying a plating current for a sufficient duration of time, which is typically a few seconds, plating deposits can be formed in pinholes 13 using material provided by the plating material precursor in the plating solution 140. The pinholes 13 provide access to the conductive layer 11, which serves as an electrode of the system 100.

Note that only the surface of the conductive layer 11 that contains the pinholes 13 should be exposed to the solution 140. All other surfaces of the conductive layer 11 should be covered, e.g., by a polymer 151, to prevent unwanted plating on those surfaces, which may prevent the desired plating at the pinhole 13 defects. A conductive layer 11 formed over an insulating substrate 9, e.g., glass, may not require such additional polymer 151 as the substrate 9 provides insulation from the plating bath. FIG. 2A shows an optional substrate 9 over which the conductive layer 11 has been formed. When the substrate 9 is conductive, e.g., stainless steel foil, a polymer 151 should be used. When the substrate 9 is not conductive, e.g., glass, the polymer 151 is not required.

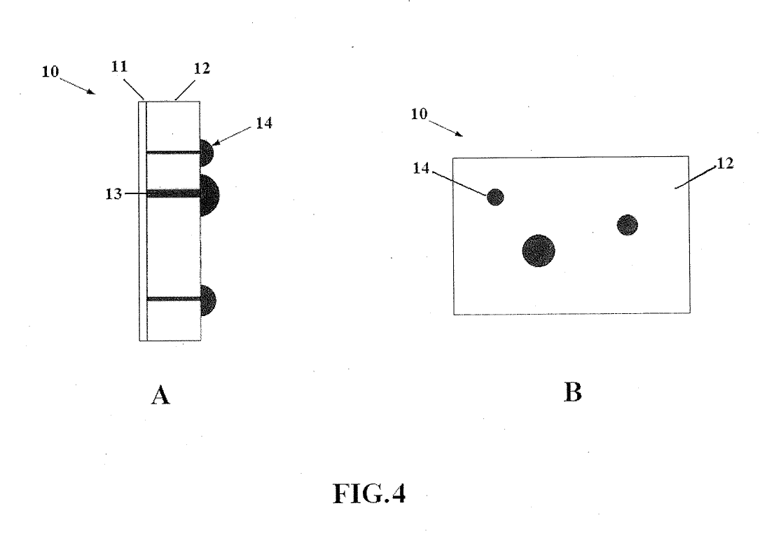

As shown in FIGS. 4A and 4B, when the current is applied in the electroplating embodiment, the pinholes 13 are filled by and covered with perceptible defect markers 14, which are deposits of plating material formed in the pinholes 13 and on the surface of the thin film coating 12. Time is a controlling factor in the deposition of sufficient material and typically, mere seconds is sufficient to deposit a marker 14. Visually identifying material deposition during these few seconds is one way to confirm the process.

The plating material precursor in solution 140 can include metals with low reduction potential (e.g. gold, silver, copper, nickel, platinum, rhodium, or palladium). Reduction potential (also known as redox potential, oxidation/reduction potential, ORP or Eh) is a measure of the tendency of a chemical species to acquire electrons and thereby be reduced. Solutions with plating materials with lower reduction potentials are easier to plate and will more easily form markers 14 on the pinhole defects 13.

In the electroplating embodiment, the plating material precursor in solution 140 can be plated at either galvanostatic (the working electrode is maintained at a constant current) or potentiostatic (the working electrode is maintained at a constant electric potential) mode. The galvanostatic mode is capable of keeping the plating current in a constant range or value, disregarding changes in the load itself. The potentiostatic mode can hold the electric potential constant during the plating, normally using a potentiostat. In some embodiments, potentiostatic (sometimes referred to as “bulk electrolysis”) is preferred for a better plating result due to the ability to selectively plate only desired material using this technique. The plating solutions 140 can include the plating material precursor, e.g., metal ions with low reduction potential. The plating solutions 140 can be commercially available plating bathes, such as gold, silver, copper, nickel, platinum, rhodium, or palladium plating baths.

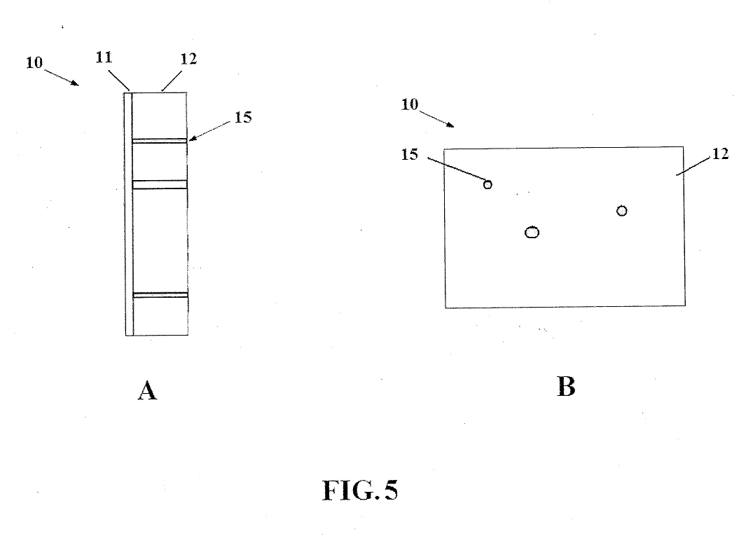

As shown in FIGS. 5A and 5B, in addition to or in place of pinhole defects 13, the thin film coating 12 of the exemplary PV module 10 can include electrical shunts 15, which can potentially form unwanted conductive paths through the thin film coating 12. Like pinholes (13 in FIGS. 2A and 2B), electrical shunts 15 can result from imperfection in the growth/deposition process of the thin film coating 12. For example, during a formation of the thin film coating 12 as a copper indium gallium (di)selenide (CIGS) semiconductor absorber layer over a metal back contact layer of a PV module 10, copper-rich particles embedded in the growing film (which can be formed by, e.g., the co-evaporation or co-sputtering of copper, gallium, and indium followed by an anneal step) can create spots of relatively highly concentrated conductive material. Such a relatively conductive spot in the thin film coating 12 creates a shunt 15 and can form an electrically conductive path through the thin film coating 12 and to the electrically conductive layer 11 (e.g., through the absorber layer to the back contact layer). It is difficult to detect an electrical shunt 15, since there may be no visible contrast between the shunt 15 path and the surface of thin film coating 12. However, because of the conductive nature of the electrical shunt 15, electroplated material can grow at the position of electrical shunt 15 using the disclosed systems and methods because the shunt 15 serves as an extension of the conductive layer 11 to the surface of the thin film coating 12 at which plating material will deposit.

Further, for detecting electrical shunts 15 (FIGS. 5A and 5B), plating material can be any suitable material that provides a detectable contrast to thin film coating 12. Detection of this contrast can occur by, for example, reflection of visible or invisible light, light scattering, light absorption, or imaging. Detection of this contrast may also occur, for example, through chemical detection by radiation absorption, fluorescence, or any other suitable material analysis technique. In some embodiments, the plating time can be adjusted for forming defect markers 14 of a suitable dimension. As in the pinhole 13 plating embodiment, the preferred plating materials for use in the shunt 14 plating embodiment are those metals that have low reduction potentials, such as gold, silver, copper, nickel, platinum, rhodium, or palladium, which can be provided in plating solution 140 (or by the anode 160, FIG. 3) as precursors.

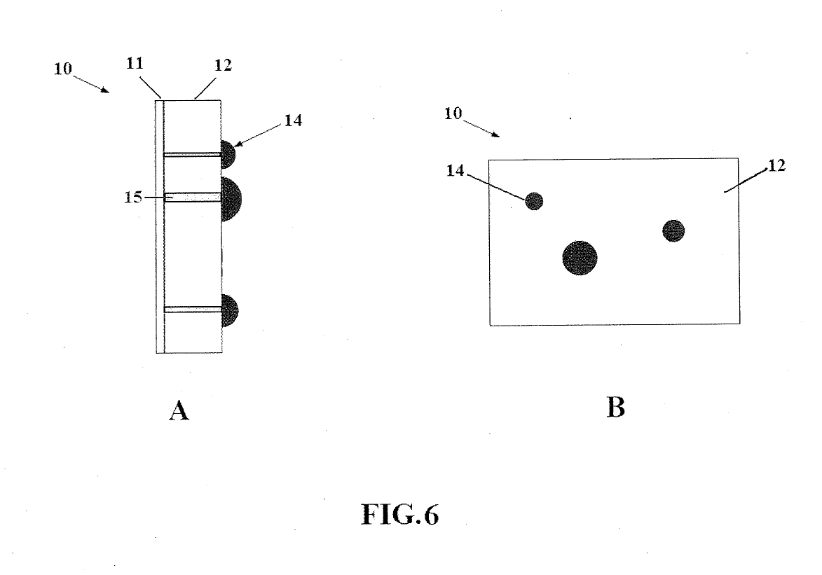

By applying a plating current as described (FIG. 3), plating deposits can be formed adjacent to the spots of electrical shunts 15. As shown in FIGS. 6A and 6B, sufficient plating material is plated at the spots of electrical shunt 15 on the surface of the thin film coating 12. The plated material can grow into perceivable (visibly or otherwise) defect markers 14 made up of deposits of plating material on the surface of thin film coating 12 so as to be more readily detected during inspection of the PV module 10. Such inspection can include detecting a contrast between the defect marker 14 and the surface of the thin film coating 12 with one or more of, for example, visual inspection, light scattering, light absorption, light reflection, x-ray absorption, x-ray fluorescence, and mechanical detection.

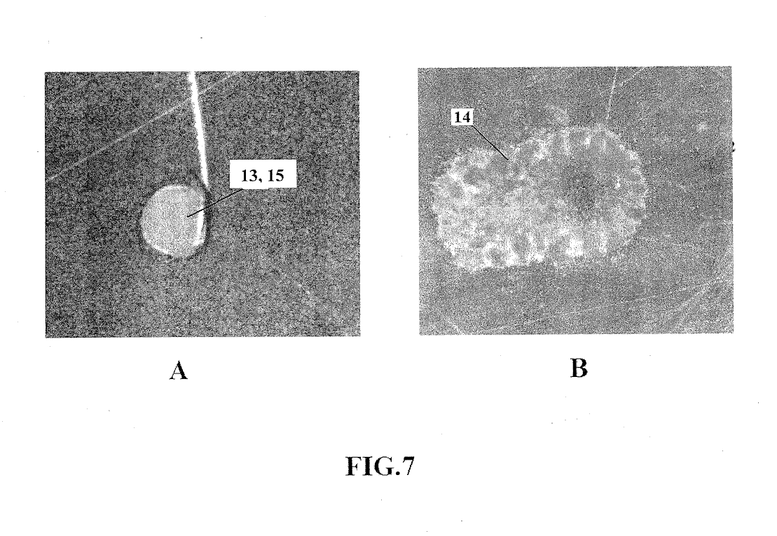

In an example, a multilayer structure formed of TCO/CdS/CdTe layers can be plated with Cu using the electroplating embodiment system 100 shown in FIG. 3. In such an example, a marker 14 for a defect 13, 15 in the CdS/CdTe film is formed when such a multilayer structure is provided in 1M solution (e.g., 140, FIG. 3) of CuCl₂ at 5 mA/cm² for 5 minutes or less. This example is shown in FIGS. 7A and 7B, which are reproduced photographs showing results of an embodiment of the disclosed methods in use. As shown, the formed defect marker 14 (FIG. 7B) is much larger than the original defect 13, 15 (FIG. 7A) because of overplating (meaning, excessively plating, rather than merely covering the defect 13 and mirroring its size, to form a larger visible marker). The defect 13, 15 shown in FIG. 7A is about 50 μm across and the defect marker 14 shown in FIG. 7B is more than 500 μm across.

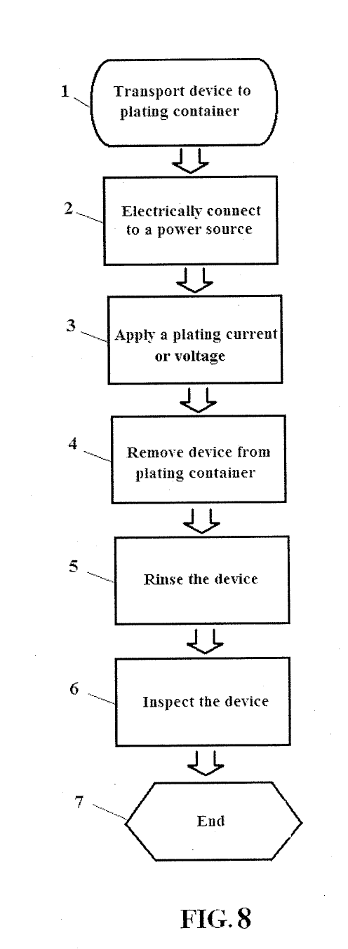

FIG. 8 illustrates a method for forming defect markers 14 for identifying pinholes 13 and/or electrical shunts 15, which can include the steps of: (1) transporting a partially completed device (e.g., the PV module 10) to a plating container; (2) electrically connecting the conductive layer and the anode, respectively, to a power source; (3) applying a plating current or voltage for sufficient time to form a defect marker 14 on the thin film (e.g., 12) surface; (4) removing the device from the plating container; (5) rinsing the device to remove any solution or contaminants; (6) optically inspecting the thin film surface; and (7) ending.

The procedure, which can include or be followed by evaluating the pinhole/electrical shunt 13, 15 defect marker 14 number, density, and/or locations. Thereafter, the thin film 12 growth/deposition process can be adjusted, if necessary, for subsequent PV module 10 manufacturing to prevent similar defects from occurring during the processing of other PV modules 10.

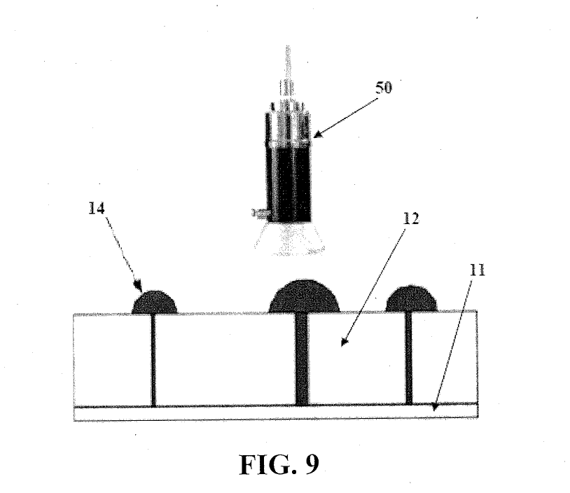

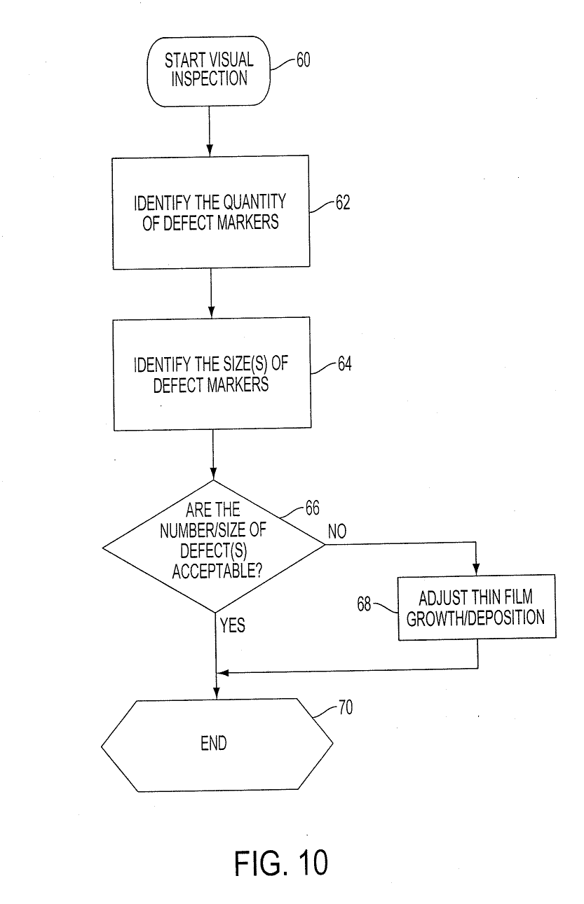

In an embodiment as shown in FIG. 9, a pinhole 13 and/or electrical shunt 15 detection and evaluation process can include optically inspecting the thin film surface with any suitable device 50, such as optical microscopes, scanning electron microscopes (SEMs), or systems employing cameras. An evaluation of the defect markers 14 can be performed as described below with reference to FIG. 10. As discussed above, inspection for defects is not limited to a visual detection process and can include a variety of other techniques as well.

In some embodiments, as shown in FIG. 10, the disclosed method can further include an evaluation of the defects 13, 15 identified by observing the markers 14, which can include defining size, location, and quantity values for defect markers 14. For example, the size of the defect marker 14 can correspond to the magnitude of a pinhole 13 or electrical shunt 15. An automated optical inspection system, for example, can be used to count the number/density of point defects at a high speed to judge the deposition quality of the surveyed film 12. Thus, FIG. 10 shows further processing steps, subsequent to step 7 shown in FIG. 8. During the visual inspection 60, the system can identify 62 the quantity of defect markers 14 on the thin film 12. This can be paired with or followed by the step 64 of identifying the sizes of the defect markers 14 on the thin film 12. These steps provide an indicator of how good the thin film 12 growth/deposition process was that formed the portion of the PV module 10 being inspected. It can next be determined 66, based on the number, location, and/or size of defects 14 identified, whether the processing that formed the thin film 12 is acceptable. If it is acceptable, the process can be ended 70. If it is not acceptable, the thin film's 12 growth/deposition processing can be adjusted 68 as necessary to form acceptable thin films.

In some embodiments, the pinhole 13 and electrical shunt 15 detection system and related method can be used to inspect thin films of PV devices, such as cadmium telluride absorber layer PV modules or CIGS absorber layer PV modules. The conductive layer (11 in FIGS. 2A and 2B) can be a TCO stack for cadmium telluride containing PV devices (e.g., the PV module 1000 of FIG. 1), or a back contact for CIGS containing PV devices. The thin film (12 in FIGS. 2A and 2B) for inspection can accordingly be the CdTe or CIGS absorber layers.

In some embodiments, the pinhole 13 and/or electrical shunt 15 detection process can be integrated into a production manufacturing flow, providing real-time, in-line inspection of the thin film growth/deposition process. In some embodiments, the pinhole 13 and/or electrical shunt 15 detection system and related method can be used in manufacturing of other semiconductor devices (such as diodes, capacitors, and transistors) with a conductor-insulator or conductor-semiconductor interface(s). In preferred embodiments, the defect marker 14 can visually contrast with the non-conductive thin film 12.

A number of embodiments have been described. Nevertheless, it will be understood that various modifications may be made thereto without departing from the scope of the invention. It should also be understood that the appended drawings are not necessarily to scale, presenting a somewhat simplified representation of various preferred features illustrative of the basic principles of the invention. The invention should not be limited to any particular embodiment or feature disclosed, but is defined by the appended claims.

What is claimed is:

1. A method for detecting a defect in a photovoltaic device structure, comprising:
providing a photovoltaic device structure comprising a conductive electrode layer and at least one additional layer adjacent the conductive electrode layer, the at least one additional layer comprising a semiconductor material or a dielectric material and having the defect; and
forming a defect marker over the defect by plating the defect.

2. The method of claim 1, wherein the at least one additional layer is a semiconductor layer.

3. The method of claim 1, wherein the at least one additional layer comprises one of a window layer and an absorber layer of the photovoltaic device structure.

4. The method of claim 1, wherein the conductive electrode layer comprises one of a transparent conductive oxide layer and a back contact layer of the photovoltaic device structure.

5. The method of claim 1, wherein the defect is at least one of a pinhole and an electrical shunt in the at least one additional layer.

6. The method of claim 1, wherein the defect marker is formed by contacting the structure with a plating solution.

7. The method of claim 1, wherein the defect marker is formed by electroplating.

8. The method of claim 1, wherein the defect marker is plated using a material selected from the group consisting of gold, silver, copper, nickel, platinum, rhodium, and palladium.

9. The method of claim 1, wherein the at least one additional layer comprises one of a layer of CdTe and a layer of CIGS.

10. The method of claim 1, wherein a contrast between the defect marker and the surface of the at least one additional layer is detected using at least one of visual inspection, light scattering inspection, light absorption inspection, light reflection inspection, x-ray absorption inspection, x-ray fluorescence inspection, and mechanical detection.

11. A method of inspecting a portion of a photovoltaic module for defects, comprising:
placing a portion of a photovoltaic module having a conductive electrode layer and at least one adjacent layer in a solution to create a defect marker corresponding to a defect in the adjacent layer.

12. The method of claim 11, wherein the defect can be as small as 10 nm.

13. The method of claim 11, wherein the at least one adjacent layer comprises one of an insulating layer, a semiconductor layer, a window layer and an absorber layer.

14. The method of claim 11, further comprising submitting the at least one layer to inspection for defects, wherein the inspection comprises the use of microscopy.

15. The method of claim 11, further comprising:
connecting the conductive electrode layer to a first terminal of a power source;
placing the portion of the photovoltaic module in a solution containing plating material; and
providing a conductor in the solution containing plating material, the conductor being connected to a second terminal of the power source.

16. A system for detecting a defect in a portion of a photovoltaic module, comprising:
a container suitable for holding a plating solution and receiving the portion of a photovoltaic module, the portion of the photovoltaic module comprising at least an electrically conductive layer and at least one thin film adjacent the conductive layer; and
a plating solution within the container, wherein the portion of the photovoltaic module is in the plating solution.

17. The system of claim 16, further comprising:
a power source with a positive terminal and a negative terminal;
an anode for electrically connecting to the positive terminal; and
an electrical connection between the negative terminal and the electrically conductive layer of the portion of the photovoltaic module.

18. The system of claim 16, further comprising an inspection apparatus.

19. The system of claim 18, wherein the inspection apparatus comprises at least one of an optical microscope, a scanning electron microscope, and an automated camera system.

20. The system of claim 18, wherein the inspection apparatus is configured to detect the defect by at least one of visual inspection, light scattering inspection, light absorption inspection, light reflection inspection, x-ray absorption inspection, x-ray fluorescence inspection, and mechanical detection.
